(19) United States
(12) Patent Application Publication
(10) Pub. No.: US 2025/0287634 A1
(43) Pub. Date: Sep. 11, 2025

(54) P-CHANNEL DEVICE AND INTEGRATED CIRCUIT THEREOF

(71) Applicant: SOUTHERN UNIVERSITY OF SCIENCE AND TECHNOLOGY, Shenzhen (CN)

(72) Inventors: Mengyuan HUA, Shenzhen (CN); Jinjin TANG, Shenzhen (CN)

(73) Assignee: SOUTHERN UNIVERSITY OF SCIENCE AND TECHNOLOGY, Shenzhen (CN)

(21) Appl. No.: 18/748,187

(22) Filed: Jun. 20, 2024

(30) Foreign Application Priority Data
Mar. 5, 2024 (CN) 202410249845.8

(51) Int. Cl. H01L 29/778; H01L 27/06; H01L 29/20; H01L 29/66

(52) U.S. Cl. CPC H10D 30/475; H10D 30/015; H10D 62/8503; H10D 84/01

(57) ABSTRACT

A P-channel device and an integrated circuit thereof are disclosed, where the P-channel device is sequentially provided with the following layers from bottom to top: a first N-type material layer, a second source being arranged on the first N-type material layer; a P-type channel layer arranged on the first N-type material layer, the P-type channel layer being provided with a groove and a first source, the gate dielectric layer being located above the groove, and a first gate being arranged on the gate dielectric layer; and a second N-type material layer located on the P-type channel layer, a first drain being arranged on the second N-type material layer. The first N-type material layer, the P-type channel layer, and the second N-type material layer are provided to form the P-channel device, so that the P-channel device obtains and maintains P-type operation logic.

### CROSS-REFERENCE TO RELATED APPLICATIONS

The present disclosure claims priority to and the benefit of Chinese Patent Application No. 202410249845.8 filed Mar. 5, 2024, the contents of which are incorporated herein by reference.

### TECHNICAL FIELD

The present disclosure relates to the field of semiconductor device technology, in particular to a P-channel device and an integrated circuit thereof.

### BACKGROUND

The wide application of semiconductor material technology in information communications, power transmission, optoelectronic devices and other fields has promoted revolutionary development in transportation, energy, manufacturing, communications and other fields. In the field of power energy, many application scenarios (such as high-voltage transmission, electric vehicle charging piles, and radar) need high-power power electronic devices that can withstand a high voltage. Conventional silicon-based devices are approaching their material theoretical limits in the field of power devices, and it is difficult to further optimize their performance greatly. Therefore, the necessity of developing power devices based on new generation wide-bandgap semiconductor materials has become increasingly prominent.

As gallium nitride (GaN) materials have the characteristics of wide bandgap and high critical electric field, a GaN-based power device has the advantage of a high breakdown voltage and can operate in high temperature, irradiation and other harsh environments. A high electron mobility transistor (HEMT) based on the GaN material uses two-dimensional electron gas of high density and high mobility generated by spontaneous and piezoelectric polarization at heterojunction interface to conduct the current. Therefore, a GaN-based HEMT device has the advantages of low on-resistance and a fast switching speed, and is one of the potential technical schemes for developing the next generation of high-frequency and high-voltage power electronic devices and power integrated circuits. At present, the performance of a GaN heterogeneous integrated circuit using a silicon-based device as a peripheral circuit is limited by the silicon device, and full potential of the GaN-based device cannot be achieved. The reason is that the silicon-based peripheral circuit needs to be interconnected with the GaN device through a metal wire, and thus a parasitic inductance is introduced to seriously affect stability of the circuit. In addition, due to a narrow operating temperature range and weak radiation resistance of the silicon device, application scenarios of the GaN heterogeneous integrated circuit are seriously limited. Realizing an all-GaN integrated circuit on the same epitaxial platform is the key to get rid of the limitation of the silicon-based peripheral circuit and release the potential of a GaN power device and a power supply system. There are two schemes to realize a GaN peripheral circuit based on current N-channel GaN devices: resistor-transistor logic circuit and direct-coupled transistor logic circuit. However, these two schemes have large static power loss. By introducing an enhanced P-channel device and N-channel device to form a complementary logic circuit, the static power loss can be eliminated and functions of a power device platform can be expanded.

However, the current density of the normally-off P-channel device on a commercially available GaN-based HEMT platform on a silicon substrate is low, which makes it difficult to match the N-channel device. By changing an epitaxial structure, two-dimensional hole gas is introduced and used as a conduction channel, so that the current density of the P-channel device can be improved to a certain extent. However, the epitaxial structure is incompatible with an existing GaN-based HEMT device on the silicon substrate, which makes it difficult to realize a GaN complementary logic circuit and seriously hinders the wide application of a GaN monolithic integrated circuit.

### SUMMARY

To solve the above problem, the present disclosure aims to provide a P-channel device and an integrated circuit thereof. A first N-type material layer, a P-type channel layer, and a second N-type material layer are provided on a base layer to form the P-channel device, so that the P-channel device obtains and maintains P-type operation logic. This effectively improves the current density of the P-channel device, simplifies a structure of the P-channel device, reduces the difficulty of preparation of the P-channel device and reduces production costs of the integrated circuit.

The present disclosure adopts the following technical scheme for solving the technical problem.

In accordance with a first aspect of the present disclosure, an embodiment provides a P-channel device including: a gate dielectric layer, a first source, a second source, a first drain and a first gate; where
the P-channel device is sequentially provided with the following layers from bottom to top:
a first N-type material layer, the second source being arranged on the first N-type material layer;
a P-type channel layer arranged on the first N-type material layer, the P-type channel layer being provided with a groove and the first source, the gate dielectric layer being located above the groove, and the first gate being arranged on the gate dielectric layer; and
a second N-type material layer located on the P-type channel layer, the first drain being arranged on the second N-type material layer.

The embodiment of the present disclosure provides the P-channel device, where each of the first N-type material layer, the P-type channel layer and the second N-type material layer has a multi-layer structure; and different layers of the first N-type material layer, the P-type channel layer and the second N-type material layer are composed of different main materials and doping elements, and different layers of the first N-type material layer, the P-type channel layer and the second N-type material layer have different doping concentrations.

The embodiment of the present disclosure provides the P-channel device, where a doping concentration of the first N-type material layer ranges from 0 to 10²² cm⁻³, a doping concentration of the P-type channel layer ranges from 10¹² to 10²² cm⁻³, and a doping concentration of the second N-type material layer ranges from 10¹² to 10²² cm⁻³.

The embodiment of the present disclosure provides the P-channel device, where the main materials of the first N-type material layer, the P-type channel layer and the second N-type material layer include at least one of gallium nitride, aluminum gallium nitride, indium gallium nitride, aluminum indium gallium nitride, aluminum nitride, zinc oxide, indium oxide, stannous oxide, tin oxide, copper oxide, or nickel oxide; and the doping elements of the first N-type material layer, the P-type channel layer and the second N-type material layer include at least one of silicon, magnesium, germanium, iron, carbon, or oxygen.

The embodiment of the present disclosure provides the P-channel device, where a base layer is further arranged below the first N-type material layer, and the base layer includes at least one of a substrate, a stress buffer layer, a channel layer, a barrier layer, or a P-type material layer.

The embodiment of the present disclosure provides the P-channel device, where a main material of the base layer includes, but is not limited to, gallium nitride, aluminum gallium nitride, indium gallium nitride, aluminum indium gallium nitride, aluminum nitride, silicon, silicon carbide, diamond, alumina, or gallium oxide.

The embodiment of the present disclosure provides the P-channel device, where the P-type channel layer is further provided with a first connecting electrode, a second connecting electrode, and a wire, the first connecting electrode and the second connecting electrode are respectively in contact with the P-type channel layer, and the first connecting electrode and the second connecting electrode are connected through the wire.

The embodiment of the present disclosure provides the P-channel device, where a main material of the gate dielectric layer includes at least one of alumina, aluminum nitride, aluminum oxynitride, silicon oxide, silicon nitride, silicon oxynitride, zirconium oxide, gallium nitride, aluminum gallium nitride, indium gallium nitride, aluminum indium gallium nitride, or aluminum nitride.

Embodiments of the present disclosure provide a P-channel device. A region of first N-type material layer is composed of three first N-type material layers, where Si-doped GaN with a thickness of 50 nm and a doping concentration of 1×10¹⁷ cm⁻³ is used as a first layer of the first N-type material layers, Si-doped GaN with a thickness of 150 nm and a doping concentration of 3×10¹⁸ cm⁻³ is used as a second layer of the first N-type material layers, and Si-doped GaN with a thickness of 100 nm and a doping concentration of 1×10¹⁷ cm⁻³ is used as a third layer of the first N-type material layers. Mg-doped GaN with a thickness of 100 nm and a doping concentration of 1×10¹⁹ cm⁻³ is used as the P-type channel layer. Si-doped GaN with a thickness of 60 nm and a doping concentration of 1×10¹⁹ cm⁻³ is used as the second N-type material layer. A first source is made of Ni/Au, a second source is made of Ti/Al/Ti/Au, a first gate is made of Ni/Au, a first drain is made of Ti/Al/Ti/Au, and a gate dielectric layer is made of alumina. The material of the first source is in ohmic contact with the material of the P-type channel layer, the material of the second source is in ohmic contact with the material of the first N-type material layer, and the material of the first gate is in ohmic contact with the material of the second N-type material layer.

In accordance with a second aspect of the present disclosure, an embodiment provides an integrated circuit including the P-channel device as described above.

The embodiment of the present disclosure provides the integrated circuit, further including an N-channel device and a base layer, where the base layer is located below a first N-type material layer; the N-channel device is provided with a third source, a second drain and a second gate; and the third source, the second drain and the second gate are all in contact with the base layer.

The embodiment of the present disclosure provides an integrated circuit, where the base layer includes a channel layer and a barrier layer; and a two-dimensional electron gas is further provided between the channel layer and the barrier layer.

Embodiments of the present disclosure provide an integrated circuit. A region of the first N-type material layer is composed of three first N-type material layers, Si-doped GaN with a thickness of 50 nm and a doping concentration of 1×10¹⁷ cm⁻³ is used as a first layer of the first N-type material layers, Si-doped GaN with a thickness of 150 nm and a doping concentration of 3×10¹⁸ cm⁻³ is used as a second layer of the first N-type material layers, and Si-doped GaN with a thickness of 100 nm and a doping concentration of 1×10¹⁷ cm⁻³ is used as a third layer of the first N-type material layers. Mg-doped GaN with a thickness of 100 nm and a doping concentration of 1×10¹⁹ cm⁻³ is used as the P-type channel layer. Si-doped GaN with a thickness of 60 nm and a doping concentration of 1×10¹⁹ cm⁻³ is used as the second N-type material layer. A first source is made of Ni/Au, a second source is made of Ti/Al/Ti/Au, a first gate is made of Ni/Au, a first drain is made of Ti/Al/Ti/Au, a gate dielectric layer is made of alumina, a third source is made of Ti/Al/Ti/Au, a second gate is made of Ni/Au, and a second drain is made of Ti/Al/Ti/Au. The material of the first source is in ohmic contact with the material of the P-type channel layer, the material of the second source is in ohmic contact with the material of the first N-type material layer, the material of the first drain is in ohmic contact with the material of the second N-type material layer, the material of the third source is in ohmic contact with the two-dimensional electron gas, the second drain is in ohmic contact with the two-dimensional electron gas, and the second gate is in Schottky contact with a P-type material layer.

According to embodiments of the present disclosure, the first N-type material layer, the P-type channel layer and the second N-type material layer are provided to form the P-channel device, so that the P-channel device obtains and maintains P-type operation logic. This effectively improves the current density of the P-channel device, simplifies a structure of the P-channel device and makes preparation of the P-channel device less difficult, and reduces production costs of the integrated circuit.

Additional aspects and advantages of the present disclosure will be set forth in part in the following description, and in part will be apparent from the following description, or may be learned by practice of the present disclosure.

### BRIEF DESCRIPTION OF DRAWINGS

FIG. 1 is a structural diagram of a P-channel device according to an embodiment of the present disclosure;

FIG. 2 is a structural diagram of a P-channel device according to another embodiment of the present disclosure;

FIG. 3 is a structural diagram of a P-channel device according to another embodiment of the present disclosure;

FIG. 4 is a structural diagram of a P-channel device according to another embodiment of the present disclosure;

FIG. 5 is an equivalent circuit diagram of the P-channel device in FIG. 1;

FIG. 6 is a structural diagram of an integrated circuit according to an embodiment of the present disclosure; and

FIG. 7 is a curve graph of a transfer characteristic of a P-channel device according to an embodiment of the present disclosure.

### DETAILED DESCRIPTION

Embodiments of the present disclosure will be described in detail below. Examples of the embodiments are illustrated in the accompanying drawings, where the same or like reference numerals throughout the figures indicate the same or like elements having the same or like functions. The embodiments described below with reference to the accompanying drawings are exemplary and are intended only to explain the present disclosure instead of being construed as limiting the present disclosure.

In the description of the present disclosure, it should be understood that, descriptions relating to orientation, for example, orientation or positional relationships indicated by “up”, “down”, “front”, “back”, “left”, “right”, etc. are based on the orientation or positional relationships shown in the accompanying drawings, and are to facilitate the description of the present disclosure and simplify the description only, rather than indicating or implying that the apparatus or element referred to must have a specific orientation or be constructed and operated in a specific orientation, and therefore cannot be construed as limiting the present disclosure.

In the description of the present disclosure, the meaning of “several” is one or a plurality; the meaning of “a plurality of” is two or more; “greater than”, “less than”, “more than”, etc. are to be construed as excluding a given figure; and “above”, “below”, “within”, etc. are to be construed as including a given figure. If “first” and “second”, etc. are referred to, it is only for the purpose of distinguishing technical features, and shall not be construed as indicating or implying relative importance or implying the number of the indicated technical features or implying the sequence of the indicated technical features.

In the description of the present disclosure, unless otherwise explicitly defined, the terms such as “arrange”, “install”, and “connect” should be construed in a broad sense, and those skilled in the art can determine the specific meanings of the above terms in the present disclosure in a rational way in conjunction with the specific contents of the technical schemes.

A P-channel device and an integrated circuit thereof in the embodiments of the present disclosure are HEMT devices made of GaN materials. Gallium nitride is an inorganic compound and a wide-bandgap semiconductor, with a bandgap width as high as 3.4 eV. Its conductivity and luminescence characteristics have long attracted people's attention. Currently, because a silicon-based peripheral circuit needs to be interconnected with a GaN device through a metal wire, and a parasitic inductance introduced by this will seriously affect stability of the circuit. The performance of a GaN heterogeneous integrated circuit using a silicon-based device as a peripheral circuit is limited by the silicon device, and full potential of the GaN-based device cannot be achieved. In addition, the current density of a normally-off P-channel device is quite small. For example, the current density of a conventional P-channel device is only 10 mA/mm when the voltage value is −10 V, which is difficult to match an N-channel device. The current density of the P-channel device can be improved by optimizing an epitaxial structure, but the epitaxial structure is not compatible with an existing GaN-based HEMT device on a silicon substrate, which makes it difficult to realize a GaN complementary logic circuit.

In view of this, embodiments of the present disclosure provide a P-channel device and an integrated circuit thereof. A first N-type material layer, a P-type channel layer and a second N-type material layer are provided on a base layer to form the P-channel device, so that the P-channel device obtains and maintains P-type operation logic. This effectively improves the current density of the P-channel device, simplifies a structure of the P-channel device and makes preparation of the P-channel device less difficult, and reduces production costs of the integrated circuit.

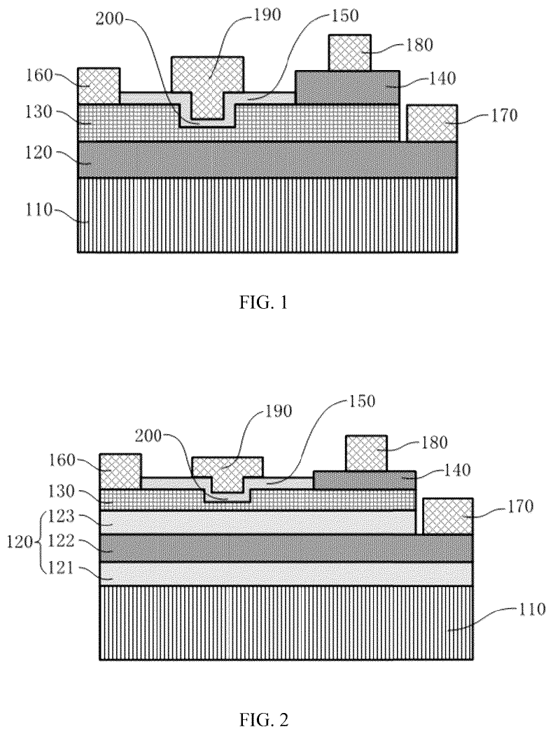

FIGS. 1 to 4 show structural diagrams of a P-channel device according to embodiments of the present disclosure. An embodiment of the present disclosure provides a P-channel device including a gate dielectric layer 150, a first source 160, a second source 170, a first drain 180, and a first gate 190. The P-channel device is sequentially provided with the following layers from bottom to top: a first N-type material layer 120, the second source 170 being arranged on the first N-type material layer 120; a P-type channel layer 130 arranged on the first N-type material layer 120, the P-type channel layer 130 being provided with a groove 200 and the first source 160, the gate dielectric layer 150 being located above the groove 200, and the first gate 190 being arranged on the gate dielectric layer 150; and a second N-type material layer 140 located on the P-type channel layer 130, the first drain 180 being arranged on the second N-type material layer 140.

By preparing a bipolar junction transistor on the first N-type material layer 120, the P-type channel layer 130 and the second N-type material layer 140, the P-channel device is formed by device preparation on the P-type channel layer 130 to control the bipolar junction transistor, so as to obtain P-type operation logic. In this way, given the same voltage value of −10 V, the current density of the P-channel device in this embodiment of the present disclosure can reach more than 100 mA/mm, thus realizing the P-channel device with a large current density.

Further, because the P-channel device prepared on the P-type channel layer 130 is only used to maintain the P-type operation logic, the current density of the P-channel device only needs to match a base current of the bipolar junction transistor, which greatly reduces technical requirements for preparing and forming the P-channel device on the P-type channel layer 130. In addition, the epitaxial structure composed of the first N-type material layer 120, the P-type channel layer 130 and the second N-type material layer 140 does not significantly affect material properties of a base layer 110, and a high-performance normally-off N-channel power device can still be prepared on the original base layer 110. Therefore, the epitaxial structure and bipolar P-channel devices can well realize an all-gallium nitride power integrated circuit.

Specifically, each of the first N-type material layer 120, the P-type channel layer 130 and the second N-type material layer 140 has a multi-layer structure; and different layers of the first N-type material layer 120, the P-type channel layer 130 and the second N-type material layer 140 are composed of different main materials and doping elements, and different layers of the first N-type material layer 120, the P-type channel layer 130 and the second N-type material layer 140 have different doping concentrations. As shown in FIG. 2, the first N-type material layer 120 is composed of three layers of first N-type material layer: a first layer of first N-type material layer 121, a second layer of first N-type material layer 122, and a third layer of first N-type material layer 123. In actual application, Si-doped GaN with a thickness of 50 nm and a doping concentration of 1×10¹⁷ cm⁻³ is used as the first layer of first N-type material layer 121, Si-doped GaN with a thickness of 150 nm and a doping concentration of 3×10¹⁸ cm⁻³ is used as the second layer of first N-type material layer 122, and Si-doped GaN with a thickness of 100 nm and a doping concentration of 1×10¹⁷ cm⁻³ is used as the third layer of first N-type material layer 123. In other embodiments, for each of the first N-type material layer 120, the P-type channel layer 130 and the second N-type material layer 140, the related parameters such as a main material, a doping element, the doping concentration, or the thickness can be adjusted according to an actual requirement.

Specifically, the main materials of the first N-type material layer 120, the P-type channel layer 130 and the second N-type material layer 140 include at least one of gallium nitride, aluminum gallium nitride, indium gallium nitride, aluminum indium gallium nitride, aluminum nitride, zinc oxide, indium oxide, stannous oxide, tin oxide, copper oxide, or nickel oxide; and the doping elements of the first N-type material layer 120, the P-type channel layer 130 and the second N-type material layer 140 include at least one of silicon, magnesium, germanium, iron, carbon, or oxygen. It can be understood that gallium nitride, aluminum gallium nitride, indium gallium nitride, aluminum indium gallium nitride, aluminum nitride, zinc oxide, indium oxide, stannous oxide, tin oxide, copper oxide, or nickel oxide have the advantages of good chemical stability, extremely high melting point, high thermal conductivity, hard texture and high luminous efficiency. Using the foregoing materials as the main materials of the first N-type material layer 120, the P-type channel layer 130 and the second N-type material layer 140 can effectively ensure good stability of the P-channel device. The doping elements of the first N-type material layer 120, the P-type channel layer 130 and the second N-type material layer 140 include at least one of silicon, magnesium, germanium, iron, carbon, or oxygen. It can be understood that doping some trace elements as impurities in an intrinsic semiconductor can significantly change conductivity of the semiconductor. By doping a small amount of elements such as silicon, magnesium, germanium, iron, carbon and oxygen, free electrons and holes exist in the first N-type material layer 120, the P-type channel layer 130 and the second N-type material layer 140, thus further ensuring good conductivity of the P-channel device.

Specifically, a doping concentration of the first N-type material layer 120 ranges from 0 to 10²² cm⁻³, a doping concentration of the P-type channel layer 130 ranges from 10¹² to 10²² cm⁻³, and a doping concentration of the second N-type material layer 140 is ranges from 10¹² to 10²² cm⁻³.

It can be understood that selection of the doping element, doping concentration, and main material for one of the first N-type material layer 120, the P-type channel layer 130 and the second N-type material layer 140 does not affect selection of those for another. Further, a region of the first N-type material layer 120 includes the plurality of first N-type material layers 120 with different doping concentrations, and a region of the P-type channel layer 130 includes a plurality of P-type channel layers 130 with different doping concentrations, therefore the selection of the doping element, doping concentration, and main material for one layer in the first N-type material layer 120 and the P-type channel layer 130 does not affect selection of those for another layer. For example, in order to ensure structural stability of the P-type channel layer 130 and reduce production costs, the doping concentration of each layer in the P-type channel layer 130 can be selected from a range of 10¹² to 10²² cm⁻³ and different doping concentrations are used for different layers, to reduce the production costs of the P-type channel layer 130 and make production less difficult on the premise of ensuring overall performance of the P-type channel layer 130.

Further, a thickness of the first N-type material layer 120 ranges from 10 nm to 300 nm, a thickness of the P-type channel layer 130 ranges from 10 nm to 300 nm, and a thickness of the second N-type material layer 140 ranges from 10 nm to 200 nm.

The following illustrates influence of the thickness of the P-type channel layer 130 on the current density in an embodiment.

TABLE 1

| | Thickness (nm) | | | | | | | | | |
|---|---|---|---|---|---|---|---|---|---|---|
| | 5 | 10 | 30 | 60 | 90 | 120 | 150 | 200 | 300 | 400 |
| Current | 9.8 | 263.6 | 412.5 | 326.7 | 265.2 | 152.2 | 100.5 | 87.6 | 63.2 | 10.5 |
| density | | | | | | | | | | |
| (mA/mm) | | | | | | | | | | |

As shown in Table 1, when the thicknesses of other layers remain unchanged, different thicknesses of the P-type channel layers 130 have a significant effect on the current density. It can be understood that when the thickness of the P-type channel layer 130 is less than 10 nm, the P-channel device prepared on the P-type channel layer 130 has a large on-resistance, and thus has a very low current density, thereby it is impossible to drive the bipolar junction transistor composed of the first N-type material layer 120, the P-type channel layer 130 and the second N-type material layer 140. Therefore, in the actual production, the P-type channel layer 130 with a thickness greater than 10 nm is selected. In addition, as can be learned from Table 1, when the thickness is greater than 300 nm, the P-type channel layer 130 obviously cause the current density to drop. It can be learned that a range of the thickness of the P-type channel layer 130 provided in this embodiment can effectively improve the current density of the P-channel device.

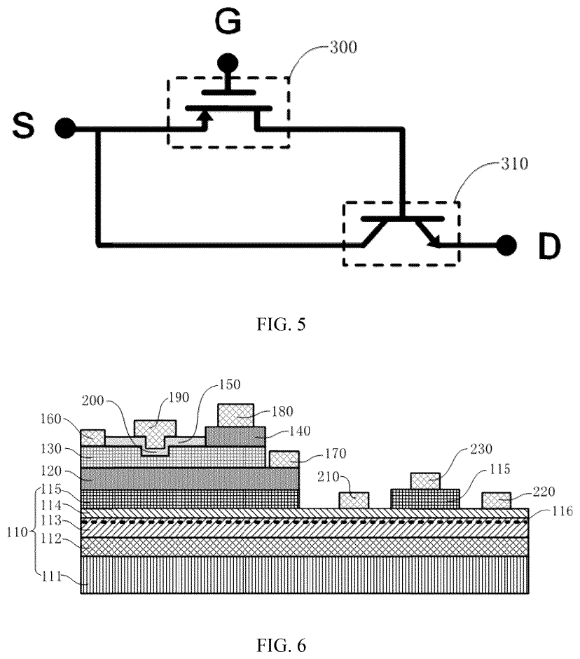

FIGS. 1 and 5 show a structure diagram of a P-channel device according to an embodiment of the present disclosure and an equivalent circuit diagram thereof, respectively. By providing the first N-type material layer 120, the P-type channel layer 130 and the second N-type material layer 140, and providing the gate dielectric layer 150, the first source 160, the first drain 180, the second source 170 and the first gate 190 on the above epitaxial structure, the P-channel device provided by this embodiment of the present disclosure can be realize as an integrated bipolar P-channel device, on the base layer 110, corresponding to the equivalent circuit as shown in FIG. 5. Specifically, the groove 200, the gate dielectric layer 150, the first gate 190, and the first source 160 constitute a main body portion of a P-type transistor 300 in FIG. 5, and the depth of the groove 200 is 0-100% of the thickness of P-type channel layer 130.

The first N-type material layer 120, the P-type channel layer 130 and the second N-type material layer 140 constitute a main structure of an NPN bipolar junction transistor 310 in FIG. 5. By preparing the devices on the first N-type material layer 120 and the P-type channel layer 130, the P-channel device is formed to control the bipolar junction transistor to obtain the P-type operation logic, so that the compatibility and current density of the P-channel device is effectively improved.

In some embodiments, the base layer 110 is further provided below the first N-type material layer 120. The base layer 110 includes a substrate 111, a stress buffer layer 112, a channel layer 113, a barrier layer 114, and a P-type material layer 115 which are stacked in sequence. A surface on a side of the P-type material layer 115 is in contact with a surface on a side of the first N-type material layer 120. It can be understood that the first N-type material layer 120 and the P-type material layer 115 are tightly bonded to effectively ensure structural stability of the P-channel device.

Specifically, the substrate 111 may be, but is not limited to, silicon, silicon carbide, gallium nitride, aluminum nitride, sapphire, or diamond, and a thickness of the substrate 111 ranges from 0.1 mm to 1 mm. A thickness of the stress buffer layer 112 ranges from 1 μm to 10 μm, and the stress buffer layer 112 is made of nitride. Specifically, the material of the stress buffer layer 112 may be, but is not limited to, at least one of gallium nitride, aluminum nitride, aluminum gallium nitride, indium gallium nitride, or indium aluminum gallium nitride. A thickness of the channel layer 113 ranges from 50 nm to 600 nm, and the material of the channel layer 113 is selected from at least one of gallium nitride, aluminum nitride, aluminum gallium nitride, or indium gallium nitride. A thickness of the barrier layer 114 ranges from 1 nm to 100 nm, and the material of the barrier layer 114 may be, but is not limited to, at least one of aluminum gallium nitride, gallium nitride, aluminum nitride, indium gallium nitride, or indium aluminum gallium nitride. A thickness of the P-type material layer 115 ranges from 1 nm to 200 nm, and the material of the P-type material layer 115 may be, but is not limited to, at least one of aluminum gallium nitride, gallium nitride, aluminum nitride, indium gallium nitride, or indium aluminum gallium nitride.

In this embodiment, the groove 200, the gate dielectric layer 150, the first gate 190, and the first source 160 are located on the P-type channel layer 130 to constitute a P-type transistor. In other embodiments, the P-type channel layer 130 and the P-type material layer 115 are made of the same material, therefore the groove 200, the gate dielectric layer 150, the first gate 190, and the first source 160 can alternatively be located on the base layer 110. Alternatively, the P-type channel layer 130 can be used as the base layer 110 to support the groove 200, the gate dielectric layer 150, the first gate 190, and the first source 160, thus further simplifying a structure of the P-channel device and improving flexibility of combination for the P-channel device.

It can be understood that a production process of the epitaxial structure and the base layer 110 in this embodiment of the present disclosure mainly includes the following steps:
At S1000, the substrate 111 is provided.
At S1100, the stress buffer layer 112 is formed on the substrate 111. A method for forming the stress buffer layer 112 may be, but is not limited to, at least one of chemical vapor deposition, molecular beam epitaxy, atomic layer deposition, vacuum ion plating, or magnetron sputtering.
At S1200, the channel layer 113 is formed on the stress buffer layer 112. A method for forming the channel layer 113 may be, but is not limited to, at least one of chemical vapor deposition, molecular beam epitaxy, atomic layer deposition, vacuum ion plating, or magnetron sputtering.
At S1300, the barrier layer 114 is formed on the channel layer 113. A method for forming the barrier layer 114 may be, but is not limited to, at least one of chemical vapor deposition, molecular beam epitaxy, atomic layer deposition, vacuum ion plating, or magnetron sputtering.
At S1400, the P-type material layer 115 is formed on the barrier layer 114. A method for forming the P-type material layer 115 may be, but is not limited to, at least one of chemical vapor deposition, molecular beam epitaxy, atomic layer deposition, vacuum ion plating, or magnetron sputtering. Here, a process of doping an element may use, but is not limited to, ion injection and high-temperature annealing activation, or a low energy electron radiation activation method.
At S1500, the first N-type material layer 120 is formed on the P-type material layer 115. A manner of forming the first N-type material layer 120 may be, but is not limited to, at least one of chemical vapor deposition, molecular beam epitaxy, atomic layer deposition, vacuum ion plating, or magnetron sputtering. A process of doping an element may use, but is not limited to, ion injection and high-temperature annealing activation, or the low energy electron radiation activation method. Similarly, the first N-type material layer 120 may be formed in a selective region or in a full region.
At S1600, the P-type channel layer 130 is formed on the first N-type material layer 120. A manner of forming the P-type channel layer 130 may be, but is not limited to, at least one of chemical vapor deposition, molecular beam epitaxy, atomic layer deposition, vacuum ion plating, or magnetron sputtering. A process of doping an element may use, but is not limited to, ion injection and high-temperature annealing activation, or the low energy electron radiation activation method. Similarly, the P-type channel layer 130 may be formed in a selective region or in a full region.
At S1700, the second N-type material layer 140 is formed on the P-type channel layer 130. A manner of forming the second N-type material layer 140 may be, but is not limited to, at least one of chemical vapor deposition, molecular beam epitaxy, atomic layer deposition, vacuum ion plating, or magnetron sputtering. A process of doping an element may use, but is not limited to, ion injection and high-temperature annealing activation, or the low energy electron radiation activation method. The second N-type material layer 140 may be formed in a selective region or in a full region.

As shown in FIGS. 1 to 3, in some embodiments, the P-type channel layer 130 is provided with the groove 200, which is located between the first source 160 and the second N-type material layer 140. The gate dielectric layer 150 is in contact with the groove 200 and the second N-type material layer 140, and the first gate 190 is in contact with the gate dielectric layer 150. The first source 160 is in ohmic contact or Schottky contact with the P-type channel layer 130. The second source 170 is in ohmic contact or Schottky contact with the first N-type material layer 120, and the first drain 180 is in ohmic contact or Schottky contact with the second N-type material layer 140. Specifically, the material of the gate dielectric layer 150 may be, but is not limited to, at least one of alumina, aluminum nitride, aluminum oxynitride, silicon oxide, silicon nitride, silicon oxynitride, or zirconium oxide. The material of the first gate 190 may be, but is not limited to, at least one of titanium, aluminum, nickel, gold, chromium, titanium nitride, tungsten, or nickel oxide. The first source 160, the second source 170, and the first drain 180 may be made of at least one of titanium, aluminum, nickel, gold, chromium, titanium nitride, tungsten, or nickel oxide.

Preferably, the material of the first source 160 is in ohmic contact with the material of the P-type channel layer 130, and the material of the first drain 180 is in ohmic contact with the material of the second N-type material layer 140. The material of the second source 170 is in ohmic contact with the material of the first N-type material layer 120. In some embodiments, the first source 160 and the second source 170 may also be connected to form the same electrode so as to facilitate connection of the P-channel device.

It can be understood that, as shown in FIGS. 1 to 3, a production process of the P-channel device in this embodiment of the present disclosure further includes the following steps:
At S2000, the second N-type material layer 140 and the P-type channel layer 130 are etched in a partial region by means of, but not limited to, inductively coupled plasma (ICP) etching and reactive ion etching on the epitaxial structure.
At S2100, the first source 160 is formed on the P-type channel layer 130, where a method for forming the first source 160 uses, but is not limited to, at least one of chemical vapor deposition, molecular beam epitaxy, atomic layer deposition, vacuum ion plating, or magnetron sputtering.
At S2200, the second source 170 is formed on the first N-type material layer 120, and the first drain 180 is formed on the second N-type material layer 140. A method for forming the second source 170 and the first drain 180 uses, but is not limited to, at least one of chemical vapor deposition, molecular beam epitaxy, atomic layer deposition, vacuum ion plating, or magnetron sputtering.
At S2300, the groove 200 is formed on the P-type channel layer 130 by using methods of ICP etching and reactive ion etching.
At S2400, the gate dielectric layer 150 is formed on the groove 200. A method for forming the gate dielectric layer 150 uses, but is not limited to, at least one of chemical vapor deposition, molecular beam epitaxy, atomic layer deposition, vacuum ion plating, or magnetron sputtering.
At S2500, the first gate 190 is formed on the gate dielectric layer 150. A method for forming the first gate 190 uses, but is not limited to, at least one of chemical vapor deposition, molecular beam epitaxy, atomic layer deposition, vacuum ion plating, or magnetron sputtering.

It can be understood that the P-channel device prepared by the above steps S2000 to S2500 is a bipolar P-channel device. By preparing the P-channel device on the P-type channel layer 130, the bipolar junction transistor is controlled to obtain the P-type operation logic, so that a P-channel device with a large current density can be realized.

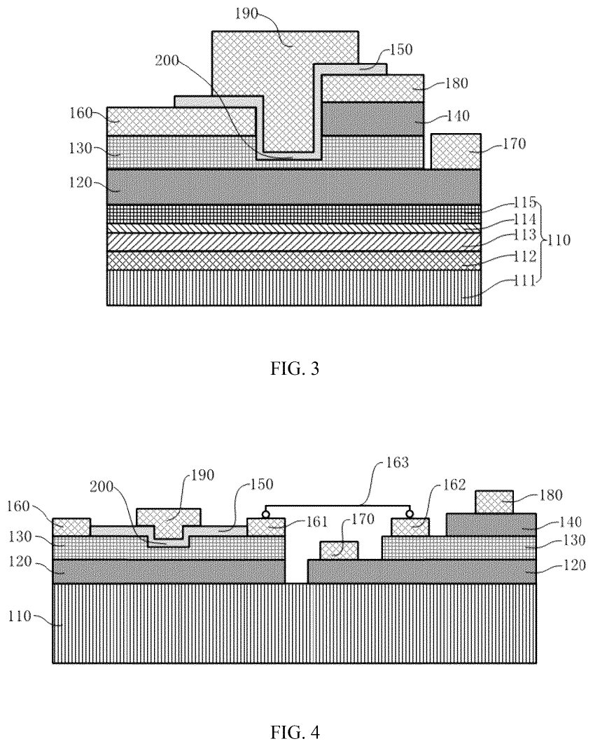

As shown in FIG. 4, in some embodiments, a first connecting electrode 161, a second connecting electrode 162, and a wire 163 are further provided on the P-type channel layer 130. The first connecting electrode 161 and the second connecting electrode 162 are respectively in contact with the P-type channel layer 130. The first connecting electrode 161 and the second connecting electrode 162 are connected through the wire 163. In some embodiments, the first connecting electrode 161 and the second connecting electrode 162 may also be connected to form the same electrode so as to facilitate the connection of the P-channel device.

In some embodiments, the P-type channel layer 130 is provided with the groove 200, which is located between the first source 160 and the first connecting electrode 161; and each of the first source 160, the first connecting electrode 161, and the second connecting electrode 162 is in ohmic contact or Schottky contact with the P-type channel layer 130. Specifically, the first source 160, the second source 170, the first drain 180, the first connecting electrode 161, the second connecting electrode 162, and the wire 163 may be made of at least one of titanium, aluminum, nickel, gold, chromium, titanium nitride, tungsten, or nickel oxide.

Preferably, the material of the first source 160 is in ohmic contact with the material of the P-type channel layer 130, the material of the first drain 180 is in ohmic contact with the material of the second N-type material layer 140, the material of the second source 170 is in ohmic contact with the material of the first N-type material layer 120, the first connecting electrode 161 is in ohmic contact with the P-type channel layer 130, and the second connecting electrode 162 is in ohmic contact with the P-type channel layer 130.

It can be understood that, as shown in FIG. 4, the production process of the P-channel device in this embodiment of the present disclosure further includes the following steps:
At S3000, the second N-type material layer 140 and the P-type channel layer 130 are etched in a partial region by means of, but not limited to ICP etching and reactive ion etching on the epitaxial structure.
At S3100, the first source 160, the first connecting electrode 161, and the second connecting electrode 162 are formed on the P-type channel layer 130. A method for forming the first source 160, the first connecting electrode 161, and the second connecting electrode 162 uses, but is not limited to, at least one of chemical vapor deposition, molecular beam epitaxy, atomic layer deposition, vacuum ion plating, or magnetron sputtering.
At S3200, the second source 170 is formed on the first N-type material layer 120, and the first drain 180 is formed on the second N-type material layer 140. A method for forming the second source 170 and the first drain 180 uses, but is not limited to, at least one of chemical vapor deposition, molecular beam epitaxy, atomic layer deposition, vacuum ion plating, or magnetron sputtering.
At S3300, the groove 200 is formed on the P-type channel layer 130 by using methods of ICP etching and reactive ion etching.
At S3400, the gate dielectric layer 150 is formed on the groove 200. A method for forming the gate dielectric layer 150 uses, but is not limited to, at least one of chemical vapor deposition, molecular beam epitaxy, atomic layer deposition, vacuum ion plating, or magnetron sputtering.
At S3500, the first gate 190 is formed on the gate dielectric layer 150. A method for forming the first gate 190 uses, but is not limited to, at least one of chemical vapor deposition, molecular beam epitaxy, atomic layer deposition, vacuum ion plating, or magnetron sputtering.
At S3600, the wire 163 is formed between the first connecting electrode 161 and the second connecting electrode 162. A method for forming the wire 163 includes, but is not limited to, metal wire bonding, metal wire connection, chemical vapor deposition, molecular beam epitaxy, atomic layer deposition, vacuum ion plating, or magnetron sputtering.

It can be understood that the P-channel device prepared by the above steps S3000 to S3600 is a cascaded P-channel device. By preparing a plurality of P-channel devices on the P-type channel layer 130, the cascaded P-channel device is formed, thereby improving compatibility and scalability of the P-channel device, so that a P-channel device with a large current density can be realized.

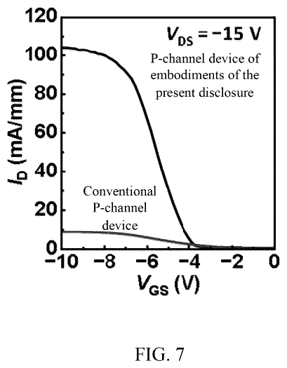

FIG. 6 is a structural diagram of an integrated circuit according to an embodiment of the present disclosure. An embodiment of the present disclosure provides an integrated circuit including the P-channel device as described above and an N-channel device arranged on a base layer 110.

In some embodiments, a two-dimensional electron gas 116 is provided between a channel layer 113 and a barrier layer 114. It can be understood that, a two-dimensional electron gas is a system in which electron groups are confined, by a physical method of quantum confinement or the like, to move in one direction to a small range, but are free to more in the other two dimensions. If an electron density in the system is low, the system is called a two-dimensional electron gas. In actual application, the two-dimensional electron gas 116 is formed between the barrier layer 114 and the channel layer 113 by introducing at least one of spontaneous polarization or piezoelectric polarization. Because the channel layer 113 and the barrier layer 114 are made of materials with different bandgap widths, a band step is formed at an interface between the channel layer 113 and the barrier layer 114. Because polarization charges formed by spontaneous polarization and piezoelectric polarization cause a band to bend, a triangular potential well is formed between the channel layer 113 and the barrier layer 114. Electrons are confined in the triangular potential well to form the two-dimensional electron gas 116. The two-dimensional electron gas 116 in the potential well is located on a side of an intrinsic semiconductor, and there is no scattering effect of an ionized impurity center, therefore the mobility of the two-dimensional electron gas 116 moving in a plane direction is quite high, which effectively ensures performance of the N-channel device in the integrated circuit as described above.

In some embodiments, the N-channel device includes a third source 210, a second drain 220, and a second gate 230. The third source 210 and the second drain 220 are in contact with the barrier layer 114, and the second gate 230 is in contact with a P-type material layer 115. The third source 210, the second drain 220, and the second gate 230 can be made of at least one of titanium, aluminum, nickel, gold, chromium, titanium nitride, tungsten, or nickel oxide.

Specifically, the third source 210 is in ohmic contact or Schottky contact with the material of the barrier layer 114, the second drain 220 is in ohmic contact or Schottky contact with the material of the barrier layer 114, and the second gate 230 is in ohmic contact or Schottky contact with the material of the P-type material layer 115. The third source 210 and the second drain 220 are respectively located on two sides of the second gate 230. Because an annealing process in the above production steps causes metal materials of the third source 210 and the second drain 220 to enter the barrier layer 114 from a dislocation existing in the material of the barrier layer 114, part of the metal material of the third source 210 and the metal material of the second drain 220, which enter the barrier layer 114, is in ohmic contact with the two-dimensional electron gas 116.

It can be understood that, as shown in FIG. 6, the production process of the integrated circuit in this embodiment of the present disclosure further includes the following steps:
At S4100, the P-channel device obtained in the above steps is provided, and a region is etched in a second N-type material layer 140, a P-type channel layer 130, a first N-type material layer 120, and the P-type material layer 115, to form a bipolar P-channel device as shown in FIG. 1 or a cascaded P-channel device as shown in FIG. 3. The etching method includes, but is not limited to, ICP etching and reactive ion etching.
At S4200, the third source 210 and the second drain 220 are formed on the barrier layer 114 and the second gate 230 is formed on the P-type material layer 115. The method for forming the third source 210, the second drain 220, and the second gate 230 includes, but is not limited to, at least one of metal evaporation, chemical vapor deposition, or magnetron sputtering.

It can be understood that in the integrated circuit prepared by the above steps S4100 and S4200, the first N-type material layer 120, the P-type channel layer 130 and the second N-type material layer 140 are provided on the base layer 110 to form the P-channel device, so that the P-channel device obtains and maintains P-type operation logic. This effectively improves the current density of the P-channel device, simplifies a structure of the P-channel device and makes preparation of the P-channel device less difficult, and reduces production costs of the integrated circuit.

The P-channel device and the integrated circuit of the present disclosure are described in further detail below by providing specific embodiments.

### Embodiment I

This embodiment provides a bipolar P-channel device including a base layer 110, a first source 160, a second source 170, a first drain 180, a gate dielectric layer 150, and a first gate 190. Here, the base layer 110 includes a silicon material with a thickness of 0.5 mm as a substrate 111, an AlGaN/GaN superlattice with a thickness of 4 μm as a stress buffer layer 112, GaN with a thickness of 400 nm as a channel layer 113, an AlGaN with a thickness of 15 nm as a barrier layer 114, the channel layer 113 being in contact with a two-dimensional electron gas 116 structure in the barrier layer 114, and a Mg-doped GaN with a thickness of 70 nm and a doping concentration of 3×10¹⁹ cm⁻³ as a P-type material layer 115. Si-doped GaN with a thickness of 50 nm and a doping concentration of 1×10¹⁷ cm⁻³ is used as a first layer of first N-type material layer 121, Si-doped GaN with a thickness of 150 nm and a doping concentration of 3×10¹⁸ cm⁻³ is used as a second layer of first N-type material layer 122, Si-doped GaN with a thickness of 100 nm and a doping concentration of 1×10¹⁷ cm⁻³ is used as a third layer of first N-type material layer 123, Mg-doped GaN with a thickness of 100 nm and a doping concentration of 1×10¹⁹ cm⁻³ is used as a P-type channel layer 130, and Si-doped GaN with a thickness of 60 nm and a doping concentration of 1×10¹⁹ cm⁻³ is used as a second N-type material layer 140.

The first source 160 is made of Ni/Au, the second source 170 is made of Ti/Al/Ti/Au, the first gate 190 is made of Ni/Au, the first drain 180 is made of Ti/Al/Ti/Au, and the gate dielectric layer 150 is made of alumina. The material of the first source 160 is in ohmic contact with the material of the P-type channel layer 130, the material of the second source 170 is in ohmic contact with the material of the first N-type material layer 120, and the material of the first drain 180 is in ohmic contact with the material of the second N-type material layer 140.

FIG. 7 is a curve graph of transfer characteristics of a P-channel device provided by this embodiment and a conventional P-channel device. FIG. 7 shows current density of the P-channel device of the embodiment of the present disclosure and the conventional P-channel device at different voltage values (−10 V to 0 V). It can be learned that under the same voltage value (for example, −10 V), the current density of the P-channel device of the embodiment of the present disclosure is 17 times higher than that of the conventional P-channel device.

### Embodiment II

This embodiment provides an integrated circuit including, on a same base layer 110, a P-channel device and an N-channel device which include a first source 160, a first gate 190, a first drain 180, a second source 170, a third source 210, a second gate 230, and a second drain 220. The base layer 110 includes a silicon material with a thickness of 0.5 mm as a substrate 111, an AlGaN/GaN superlattice with a thickness of 4 μm as a stress buffer layer 112, GaN with a thickness of 400 nm as a channel layer 113, an AlGaN with a thickness of 15 nm as a barrier layer 114, a two-dimensional electron gas 116 existing at an interface between the channel layer 113 and the barrier layer 114, and a Mg-doped GaN with a thickness of 100 nm and a doping concentration of 3×10¹⁹ cm⁻³ as a P-type material layer 115. Si-doped GaN with a thickness of 150 nm and a doping concentration of 3×10¹⁸ cm⁻³ is used as a first N-type material layer 120, Mg-doped GaN with a thickness of 100 nm and a doping concentration of 1×10¹⁹ cm⁻³ is used as a P-type channel layer 130, and Si-doped GaN with a thickness of 60 nm and a doping concentration of 1×10¹⁹ cm⁻³ is used as a second N-type material layer 140.

The first source 160 is made of Ni/Au, the second source 170 is made of Ti/Al/Ti/Au, the first gate 190 is made of Ni/Au, the first drain 180 is made of Ti/Al/Ti/Au, the gate dielectric layer 150 is made of alumina, the third source 210 is made of Ti/Al/Ti/Au, the second gate 230 is made of Ni/Au, and the second drain 220 is made of Ti/Al/Ti/Au. The material of the first source 160 is in ohmic contact with the material of the P-type channel layer 130, the material of the second source 170 is in ohmic contact with the material of the first N-type material layer 120, the material of the first drain 180 is in ohmic contact with the material of the second N-type material layer 140, the material of the third source 210 is in ohmic contact with the two-dimensional electron gas 116, the second drain 220 is in ohmic contact with the two-dimensional electron gas 116, and the second gate 230 is in Schottky contact with the P-type material layer 115.

In this embodiment, the N-channel device is provided on the base layer 110 of the P-channel device, so that a complementary integrated circuit is conveniently constructed. This effectively improves performance of the integrated circuit, and reduces production costs of the integrated circuit. Given the same voltage value (for example, −10 V), the current density of the integrated circuit of the embodiment of the present disclosure can reach 100 mA/mm.

The embodiments described above are only for illustration. The units described as separate components may or may not be physically separated, that is, they may be located at one place or distributed to multiple network units. Some or all of the modules can be selected according to actual needs to achieve the purpose of the embodiment.

1. A P-channel device, comprising: a gate dielectric layer, a first source, a second source, a first drain, and a first gate;
wherein the P-channel device is sequentially provided with following layers from bottom to top:
a first N-type material layer, the second source being arranged on the first N-type material layer;
a P-type channel layer arranged on the first N-type material layer, the P-type channel layer being provided with a groove and the first source, the gate dielectric layer being located above the groove, and the first gate being arranged on the gate dielectric layer; and
a second N-type material layer located on the P-type channel layer, the first drain being arranged on the second N-type material layer.

2. The P-channel device of claim 1, wherein each of the first N-type material layer, the P-type channel layer and the second N-type material layer has a multi-layer structure; and different layers of the first N-type material layer, the P-type channel layer and the second N-type material layer are composed of different main materials and doping elements, and different layers of the first N-type material layer, the P-type channel layer and the second N-type material layer have different doping concentrations.

3. The P-channel device of claim 2, wherein a doping concentration of the first N-type material layer ranges from 0 to 10²² cm⁻³, a doping concentration of the P-type channel layer ranges from 10¹² to 10²² cm⁻³, and a doping concentration of the second N-type material layer ranges from 10¹² to 10²² cm⁻³.

4. The P-channel device of claim 2, wherein the main materials of the first N-type material layer, the P-type channel layer and the second N-type material layer comprise at least one of gallium nitride, aluminum gallium nitride, indium gallium nitride, aluminum indium gallium nitride, aluminum nitride, zinc oxide, indium oxide, stannous oxide, tin oxide, copper oxide, or nickel oxide; and the doping elements of the first N-type material layer, the P-type channel layer and the second N-type material layer comprise at least one of silicon, magnesium, germanium, iron, carbon, or oxygen.

5. The P-channel device of claim 1, wherein a base layer is provided below the first N-type material layer, and the base layer comprises at least one of a substrate, a stress buffer layer, a channel layer, a barrier layer, or a P-type material layer.

6. The P-channel device of claim 5, wherein a main material of the base layer comprises, but is not limited to, gallium nitride, aluminum gallium nitride, indium gallium nitride, aluminum indium gallium nitride, aluminum nitride, silicon, silicon carbide, diamond, alumina, or gallium oxide.

7. The P-channel device of claim 1, wherein the P-type channel layer is provided with a first connecting electrode, a second connecting electrode and a wire, the first connecting electrode and the second connecting electrode are respectively in contact with the P-type channel layer, and wherein the first connecting electrode and the second connecting electrode are connected through the wire.

8. The P-channel device of claim 1, wherein a main material of the gate dielectric layer comprises at least one of alumina, aluminum nitride, aluminum oxynitride, silicon oxide, silicon nitride, silicon oxynitride, zirconium oxide, gallium nitride, aluminum gallium nitride, indium gallium nitride, aluminum indium gallium nitride, or aluminum nitride.

9. An integrated circuit, comprising the P-channel device of claim 1.

10. The integrated circuit of claim 9, wherein the integrated circuit comprises an N-channel device and a base layer, the base layer is located below a first N-type material layer; the N-channel device is provided with a third source, a second drain, and a second gate; and wherein the third source, the second drain and the second gate are all in contact with the base layer.

11. The integrated circuit of claim 10, wherein the base layer comprises a channel layer and a barrier layer; and a two-dimensional electron gas is provided between the channel layer and the barrier layer.
